(19) United States
(12) Patent Application Publication
(10) Pub. No.: US 2025/0228083 A1
(43) Pub. Date: Jul. 10, 2025

(54) DISPLAY DEVICE AND METHOD FOR MANUFACTURING THE DISPLAY DEVICE

(71) Applicant: Samsung Display Co., LTD., Yongin-si (KR)

(72) Inventors: Seung Min LEE, Yongin-si (KR); Dong Jo KIM, Yongin-si (KR); Hyun KIM, Yongin-si (KR); Seong Geun WON, Yongin-si (KR); Je Won YOO, Yongin-si (KR); Dan Bi CHOI, Yongin-si (KR); Seung Wan HONG, Yongin-si (KR); Souk June HWANG, Yongin-si (KR)

(21) Appl. No.: 18/815,588

(22) Filed: Aug. 26, 2024

(30) Foreign Application Priority Data
Jan. 9, 2024 (KR) 10-2024-0003309

(51) Int. Cl. H10K 59/127; H10K 59/12; H10K 77/10; H10K 102/00

(52) U.S. Cl. CPC H10K 59/127; H10K 59/1201; H10K 77/111; H10K 2102/311

(57) ABSTRACT

Provided are a display device and a method for manufacturing the display device. A display device includes a second substrate including a soft material, light-emitting elements above the second substrate, and a first substrate below the second substrate, including a hard material, and further including a second sub-substrate on one side of a bending area where the second substrate is bent, and a first sub-substrate on another side of the bending area, below the light-emitting elements, having a length that is about 50 times to about 200 times a length of the second sub-substrate, and including a first surface, a second surface opposite to the first surface, a first side surface between the first surface and the second surface, and adjacent to the bending area, and a first inclined surface between the first surface and the first side surface.

### CROSS-REFERENCE TO RELATED APPLICATION

The present application claims priority to, and the benefit of, Korean Patent Application No. 10-2024-0003309 filed on Jan. 9, 2024, in the Korean Intellectual Property Office, the entire disclosure of which is herein incorporated by reference.

### BACKGROUND

### 1. Field

The present disclosure relates to a display device, and a method for manufacturing the display device.

### 2. Description of the Related Art

As an information society develops, the demand for a display device for displaying an image is increasing in various forms. The display device may be a flat panel display, such as a liquid crystal display, a field emission display, or a light-emitting display panel.

The display device includes a display area for displaying images, and a non-display area located around the display area, for example, to surround the display area (e.g., in plan view). Recently, a width of the non-display area has been gradually reduced to increase immersion in the display area, and to enhance the aesthetics of the display device.

Meanwhile, in a process of manufacturing a display device, the display device may be formed by cutting a mother substrate including a plurality of display cells along a plurality of display cells formed on the mother substrate.

### SUMMARY

Aspects of the present disclosure provide a display device with reduced or minimized dead space and a method for manufacturing the display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a second substrate including a soft material, light-emitting elements above the second substrate, and a first substrate below the second substrate, including a hard material, and further including a second sub-substrate on one side of a bending area where the second substrate is bent, and a first sub-substrate on another side of the bending area, below the light-emitting elements, having a length that is about 50 times to about 200 times a length of the second sub-substrate, and including a first surface, a second surface opposite to the first surface, a first side surface between the first surface and the second surface, and adjacent to the bending area, and a first inclined surface between the first surface and the first side surface.

The length of the second sub-substrate may be about 2 mm to about 4 mm.

The length of the first sub-substrate may be about 200 mm to about 400 mm.

The first substrate may define an opening between the first sub-substrate and the second sub-substrate, wherein a length of an upper side of the opening is less than a length of a lower side of the opening.

The length of the second sub-substrate may be about 1 to about 4 times the length of the upper side of the opening.

The length of the upper side of the opening may be about 1.2 mm to about 1.8 mm.

The length of the second sub-substrate may be about 1 to about 2.5 times the length of the lower side of the opening.

The length of the lower side of the opening may be about 1.6 mm to about 2.0 mm.

An angle between the first side surface and the second surface may be less than about 60 degrees.

An angle formed by the first inclined surface and the first surface may be less than about 15 degrees.

A length of the first inclined surface may be about 120 μm or less.

The first substrate may further include a second side surface between the first surface and the second surface, and adjacent to an edge of the first substrate, and a second inclined surface between the second side surface and the first surface.

An angle formed by the second inclined surface and the second surface may be different from an angle formed by the first side surface and the second surface.

The first substrate may include glass, wherein the second substrate includes polymer resin.

According to an aspect of the present disclosure, there is provided a method for manufacturing a display device, the method including forming a first mother substrate, a second mother substrate above a first surface of the first mother substrate, and display cells on the second mother substrate, removing a portion of the first mother substrate in a bending area by spraying an etchant onto a second surface of the first mother substrate that is opposite to the first surface, irradiating a laser on the second surface along edges of the display cells, forming a first substrate by spraying an etchant on the second surface without a mask, and by cutting the first mother substrate, and forming a second substrate by patterning the second mother substrate along the edges of the display cells after the forming of the first substrate.

The first substrate may include a third surface, a fourth surface opposite to the third surface, a first side surface between the third surface and the fourth surface, and adjacent to the bending area, and a first inclined surface between the third surface and the first side surface, and adjacent to the bending area.

The first substrate may further include a second side surface between the third surface and the fourth surface, and adjacent to edges of the display cells, and a second inclined surface between the second side surface and the fourth surface, and adjacent to edges of the display cells, wherein an angle formed by the first side surface and the fourth surface is different from an angle formed by the second inclined surface and the fourth surface.

The forming of the first substrate may include forming dummies form a remainder of the first mother substrate between the display cells below the second mother substrate.

The forming of the second substrate may include removing the second mother substrate above the dummies by patterning the second mother substrate.

The method may further include attaching a circuit board and an adsorption pad to each of the display cells, and bending the second substrate, wherein the adsorption pad is attached onto the circuit board.

According to the display device and the method for manufacturing the display device according to one or more embodiments of the present disclosure, the dead space may be reduced or minimized.

However, the aspects of the embodiments are not restricted to the one set forth herein. The above and other aspects of the embodiments will become more apparent to one of daily skill in the art to which the embodiments pertain by referencing the claims.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel and a driving IC according to one or more embodiments;

FIG. 3 is a perspective view illustrating a display device according to another embodiment;

FIG. 4 is a cross-sectional view illustrating an example of a display area of a display panel according to one or more embodiments;

FIG. 5 is a cross-sectional view taken along the line X1-X1′ of FIG. 1;

FIG. 6 is a cross-sectional view illustrating a state in which the display device according to one or more embodiments of FIG. 5 is bent;

FIG. 7 is a flowchart illustrating a method for manufacturing a display device according to one or more embodiments;

FIG. 8 is a perspective view illustrating operation S100 of FIG. 7;

FIG. 9 is a cross-sectional view taken along the line X2-X2′ of FIG. 8;

FIG. 10 is a perspective view illustrating operation S200 of FIG. 7;

FIGS. 11 to 14 are cross-sectional views taken along the line X3-X3′ of FIG. 10;

FIG. 15 is a perspective view illustrating operation S300 of FIG. 7;

FIG. 16 is a cross-sectional view taken along the line X4-X4′ of FIG. 15;

FIG. 17 is a perspective view illustrating operation S400 of FIG. 7;

FIG. 18 is a cross-sectional view taken along the line X5-X5′ of FIG. 17;

FIGS. 19 and 20 are cross-sectional views taken along the line X6-X6′ of FIG. 17;

FIG. 21 is a perspective view illustrating operation S500 of FIG. 7;

FIG. 22 is a cross-sectional view taken along the line X7-X7′ of FIG. 21;

FIGS. 23 and 24 are perspective views illustrating operation S600 of FIG. 7; and

FIG. 25 is a cross-sectional view taken along the line X8-X8′ of FIG. 24.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

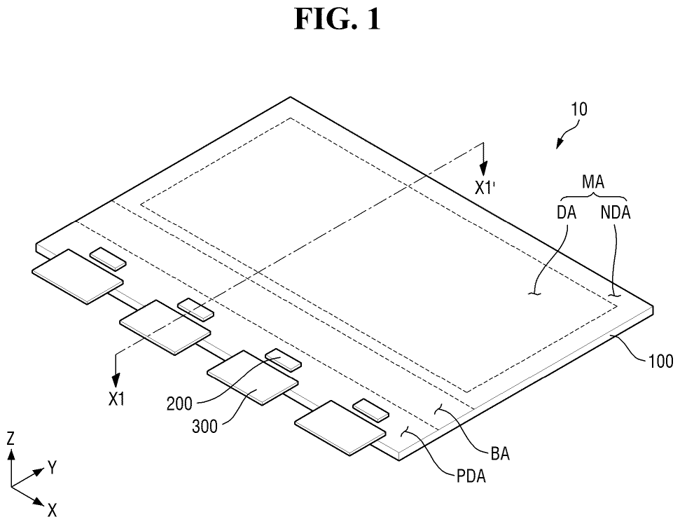

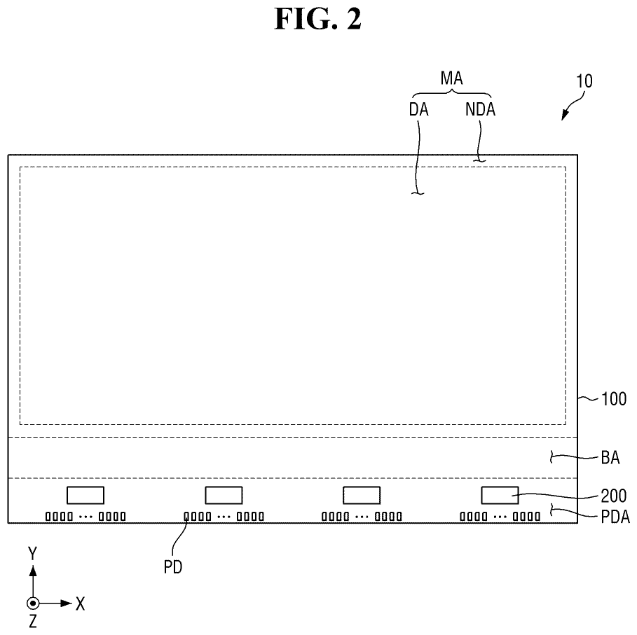

FIG. 1 is a perspective view illustrating a display device according to one or more embodiments. FIG. 2 is a plan view illustrating a display panel and a driving IC according to one or more embodiments.

Referring to FIGS. 1 and 2, a display device 10 according to one or more embodiments is a device that displays a moving image or a still image, and may be used as a display screen of each of various products, such as televisions, laptop computers, monitors, billboards, and Internet of Things (IoT), as well as portable electronic devices, such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs).

The display device 10 according to one or more embodiments may be a light-emitting display device, such as an organic light-emitting display device using an organic light-emitting diode, a quantum dot light-emitting display device including a quantum dot light-emitting layer, an inorganic light-emitting display device including an inorganic semiconductor, and a micro light-emitting display device using a micro or nano light-emitting diode (LED). Hereinafter, it is mainly described that the display device 10 is the organic light-emitting display device, but the present disclosure is not limited thereto.

The display device 10 according to one or more embodiments may include a display panel 100, a driving integrated circuit (IC) 200, and a circuit board 300.

The display panel 100 may be formed in a rectangular plane having long sides in a first direction (X-axis direction), and short sides in a second direction (Y-axis direction) crossing the first direction (X-axis direction). A corner where the long side in the first direction (X-axis direction) and the short side in the second direction (Y-axis direction) meet may be formed at a right angle, or may be rounded to have a curvature. The planar shape of the display panel 100 is not limited to the quadrangular shape, and may be formed in other polygonal shapes, a circular shape, or an elliptical shape.

In the illustrated drawings, the first direction (X-axis direction) and the second direction (Y-axis direction) are each horizontal direction and cross each other. For example, the first direction (X-axis direction) and the second direction (Y-axis direction) may be orthogonal to each other. In addition, a third direction (Z-axis direction) may be a vertical direction crossing the first direction (X-axis direction) and the second direction (Y-axis direction), for example, orthogonal to the first direction (X-axis direction) and the second direction (Y-axis direction). In the present specification, the direction indicated by the arrows in the first to third directions (X-axis direction, Y-axis direction, and Z-axis direction) may be referred to as one side, and the opposite direction thereof may be referred to as the other side.

The display panel 100 may be flat, but is not limited thereto. For example, the display panel 100 may include curved surface portions formed at left and right distal ends thereof, and having a constant curvature or a variable curvature. In addition, the display panel 100 may be flexibly curved, bent, folded, or rolled.

The display panel 100 may include a main area MA, a bending area BA, and a pad area PDA. The main area MA may include a display area DA for displaying an image, and a non-display area NDA located around the display area DA.

The display area DA may occupy most of an area of the display panel 100. The display area DA may be generally located at a center of the display panel 100. Pixels each including a plurality of light-emitting areas for displaying an image may be located in the display area DA.

The non-display area NDA may be adjacent to the display area DA. The non-display area NDA may be an area outside the display area DA. The non-display area NDA may be located to surround the display area DA (e.g., in plan view). The non-display area NDA may be an edge area of the display panel 100.

The bending area BA may be located between the display area DA and the pad area PDA in the second direction (Y-axis direction). The bending area BA may extend in the first direction (X-axis direction). The bending area BA refers to an area that is bent toward a lower portion of the display panel 100. When the bending area BA is bent toward the lower portion of the display panel 100, the plurality of driving ICs 200 and the circuit board 300 may be located at the lower portion of the display panel 100.

The pad area PDA may be a lower edge area of the display panel 100. The pad area PDA may be an area in which display pads DP connected to the circuit board 300 and first and second driving pads connected to the driving IC 200 are located.

The display pads DP may be located in the pad area PDA to be connected to the circuit boards 300. The display pads DP may be located on an edge on one side of the display panel 100. For example, the display pads DP may be located on an edge on a lower side of the display panel 100.

The driving integrated circuits (ICs) 200 may generate data voltages, power voltages, scan timing signals, etc. The driving ICs 200 may output the data voltages, the power voltages, the scan timing signals, etc.

The driving ICs 200 may be located in the pad area PDA. The driving ICs 200 may be located between the display pads DP and the display area DA in the non-display area NDA. Each of the driving ICs 200 may be attached to the non-display area NDA of the display panel 100 using a chip-on-glass (COG) method. Alternatively, the driving ICs 200 may be attached to the circuit board 300 using a chip-on-plastic (COP) manner.

The circuit boards 300 may be located on the display pads DP on the edge on one side of the display panel 100. The circuit boards 300 may be attached to the display pads DP using a conductive adhesive member, such as an anisotropic conductive film and an anisotropic conductive adhesive. Accordingly, the circuit boards 300 may be electrically connected to signal lines of the display panel 100. The circuit boards 300 may be a flexible film, such as a flexible printed circuit board or a chip on film.

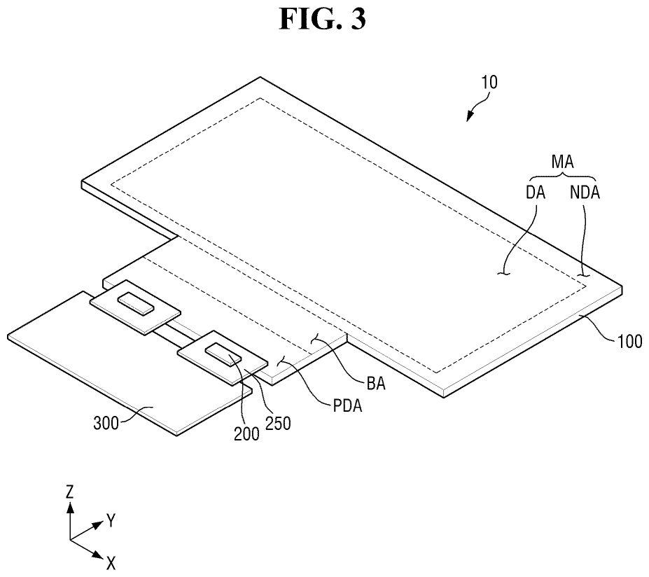

FIG. 3 is a perspective view illustrating a display device according to one or more other embodiments.

Referring to FIG. 3, the shape of the display panel 100 may be different from the shape of the display panel 100 according to the one or more embodiments described with reference to FIG. 1 and the like.

For example, in the display panel 100, a length of the main area MA in the first direction (X-axis direction) may be longer than lengths of the bending area BA and the pad area PDA. The bending area BA and the pad area PDA may have a shape that protrudes from a portion of one side of the main area MA. As an example, the display panel 100 may include an L-cut shape in which a width of the bending area BA and the pad area PDA is narrower than a width of the main area MA.

As such, the shape of the display panel 100 is not limited to the shape illustrated in FIGS. 1 to 3, and various shapes may be applied depending on the type of display device 10.

In some embodiments, the display device 10 may further include connection films 250. The connection films 250 may be flexible films.

One end of the connection films 250 may be connected to the display pads DP (see FIG. 2) of FIG. 2. The other ends of the connection films 250 may be connected to the circuit board 300. The driving ICs 200 may be located on the connection film 250. The driving ICs 200 may be mounted in a chip-on-film (COF) method. The circuit board 300 may be attached to the connection film 250.

In this way, in the pad area PDA, the driving IC 200 and the circuit board 300 may be mounted on the display panel 100 in various ways.

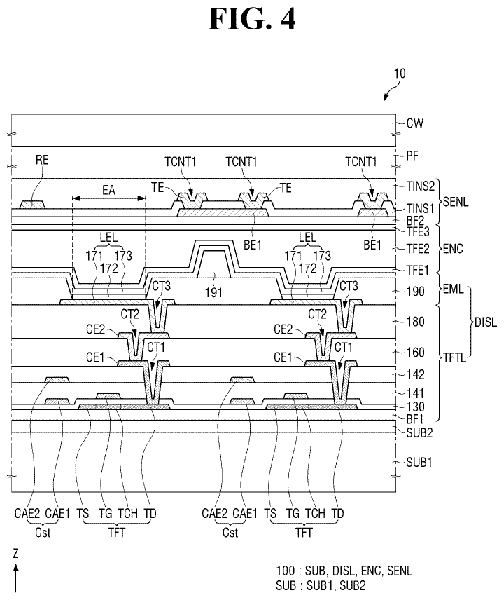

FIG. 4 is a cross-sectional view illustrating an example of a display area of a display panel according to one or more embodiments.

Referring to FIG. 4, the display device 10 may further include a display panel 100, a polarizing film PF, and a cover window CW.

The display panel 100 may be an organic light-emitting display panel including a light-emitting element LEL including an organic light-emitting layer 172. However, the display panel 100 is not limited thereto, and may also be a light-emitting display panel, such as a quantum dot light-emitting display panel including a quantum dot light-emitting layer, an inorganic light-emitting display panel including an inorganic semiconductor, and a micro or nano light-emitting display panel using a micro or nano light-emitting diode (LED). Hereinafter, for convenience of description, a case in which the display panel 100 is an organic light-emitting display panel will be described as an example.

The display panel 100 may include a substrate SUB, a display layer DISL, an encapsulation layer ENC, and a sensor electrode layer SENL.

The substrate SUB may include a first substrate SUB1 having a hard material, and a second substrate SUB2 made of a polymer resin having a soft material.

The first substrate SUB1 may have a hard material. For example, the first substrate SUB1 may be made of glass. The first substrate SUB1 may be made of ultra-thin glass (UTG) having a thickness of about 500 μm or less.

The second substrate SUB2 may have a soft material. The second substrate SUB2 may be made of a polymer resin having a thickness that is less than that of the first substrate SUB1. For example, the second substrate SUB2 may have a thickness of about 20 μm or less. The second substrate SUB2 may be formed of an organic material, such as an acryl resin, an epoxy resin, a phenolic resin, a polyamide resin, or a polyimide resin. The second substrate SUB2 may be referred to as a plastic substrate because of being made of the polymer resin. In some embodiments, the second substrate SUB2 may have a multilayer structure.

The display layer DISL may include a thin film transistor layer TFTL (e.g., circuit layer) including a plurality of thin film transistors and a light-emitting element layer EML including a plurality of light-emitting elements.

The thin film transistor layer TFTL (e.g., circuit layer) may include a first buffer film BF1, a thin film transistor TFT, a gate-insulating film 130, a first interlayer insulating film 141, a capacitor Cst, a second interlayer insulating film 142, a first data metal layer, a first organic film 160, a second data metal layer, and a second organic film 180.

A first buffer film BF1 may be located on the substrate SUB. The first buffer film BF1 may be formed of an inorganic material, such as a silicon nitride layer, a silicon oxynitride layer, a silicon oxide layer, a titanium oxide layer, and an aluminum oxide layer. Alternatively, the first buffer film BF1 may be formed as a multi-film in which a plurality of layers of a silicon nitride layer, a silicon oxynitride layer, a silicon oxide layer, a titanium oxide layer, and an aluminum oxide layer are alternately stacked.

An active layer including a channel region TCH, a source region TS, and a drain region TD of the thin film transistor TFT may be located on the first buffer film BF1. The active layer may be formed of polycrystalline silicon, single crystal silicon, low-temperature polycrystalline silicon, amorphous silicon, or an oxide semiconductor. When the active layer includes polycrystalline silicon or oxide semiconductor material, the source region TS and drain region TD in the active layer may be conductive regions that are doped with ions or impurities and have conductivity.

A gate-insulating film 130 may be located on the active layer of the thin film transistor TFT. The gate-insulating film 130 may be formed of an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of the capacitor Cst, and scan lines may be located on the gate-insulating film 130. The gate electrode TG of the thin film transistor TFT may overlap the channel region TCH in the third direction (Z-axis direction). The first gate metal layer may be formed of a single layer or multi-layer made of any one of molybdenum (Mo), aluminum (Al), chromium (Cr), gold (Au), titanium (Ti), nickel (Ni), neodymium (Nd), or copper (Cu), or alloys thereof.

A first interlayer insulating film 141 may be located on the first gate metal layer. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer, which includes a second capacitor electrode CAE2 of the capacitor Cst, may be located on the first interlayer insulating film 141. The second capacitor electrode CAE2 may overlap the first capacitor electrode CAE1 in the third direction (Z-axis direction). Therefore, the capacitor Cst may be formed by the first capacitor electrode CAE1, the second capacitor electrode CAE2, and an inorganic insulating dielectric film located therebetween and serving as a dielectric film. The second gate metal layer may be formed of a single layer or multi-layer made of any one of molybdenum (Mo), aluminum (Al), chromium (Cr), gold (Au), titanium (Ti), nickel (Ni), neodymium (Nd), or copper (Cu), or alloys thereof.

A second interlayer insulating film 142 may be located on the second gate metal layer. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

A first data metal layer, which includes a first connection electrode CE1 and data lines, may be located on the second interlayer insulating film 142. The first connection electrode CE1 may be connected to the drain region TD through a first contact hole CT1 penetrating through the gate-insulating film 130, the first interlayer insulating film 141, and the second interlayer insulating film 142. The first data metal layer may be formed of a single layer or multi-layer made of any one of molybdenum (Mo), aluminum (Al), chromium (Cr), gold (Au), titanium (Ti), nickel (Ni), neodymium (Nd), or copper (Cu), or alloys thereof.

A first organic film 160 for flattening a step caused by the thin film transistors TFT may be located on the first connection electrode CE1. The first organic film 160 may be formed of an organic film made of an acryl resin, an epoxy resin, a phenolic resin, a polyamide resin, a polyimide resin, or the like.

A second data metal layer including a second connection electrode CE2 may be located on the first organic film 160. The second data metal layer may be connected to the first connection electrode CE1 through a second contact hole CT2 penetrating through the first organic film 160. The second data metal layer may be formed of a single layer or multi-layer made of any one of molybdenum (Mo), aluminum (AI), chromium (Cr), gold (Au), titanium (Ti), nickel (Ni), neodymium (Nd), or copper (Cu), or alloys thereof.

A second organic film 180 may be located on the second connection electrode CE2. The second organic film 180 may be formed as an organic film made of an acryl resin, an epoxy resin, a phenolic resin, a polyamide resin, a polyimide resin, or the like.

In one or more embodiments, the second data metal layer, which includes the second connection electrode CE2, and the second organic film 180 may be omitted.

A light-emitting element layer EML is located on the thin film transistor layer TFTL. The light-emitting element layer EML may include light-emitting elements LEL and a pixel-defining film 190.

Each of the light-emitting elements LEL may include a pixel electrode 171, a light-emitting layer 172, and a common electrode 173. Each of the light-emitting areas EA represents an area in which the pixel electrode 171, the light-emitting layer 172, and the common electrode 173 are sequentially stacked. Holes from the pixel electrode 171 and electrons from the common electrode 173 are combined with each other in the light-emitting layer 172 to emit light. In this case, the pixel electrode 171 may be an anode electrode, and the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating through the second organic film 180. The pixel electrode layer may be formed of a single layer or multi-layer made of any one of molybdenum (Mo), aluminum (Al), chromium (Cr), gold (Au), titanium (Ti), nickel (Ni), neodymium (Nd), or copper (Cu), or alloys thereof.

In a top emission structure that emits light in a direction of the common electrode 173 from the light-emitting layer 172, the pixel electrode 171 may be formed of a single layer made of molybdenum (Mo), titanium (Ti), copper (Cu), or aluminum (Al) or be formed in a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO to increase reflectivity. The APC alloy is an alloy of silver (Ag), palladium (Pd), and copper (Cu).

The pixel-defining film 190 serves to define the light-emitting areas EA of the pixels. To this end, the pixel-defining film 190 may be formed on the second organic film 180 to expose a partial area of the pixel electrode 171. The pixel-defining film 190 may cover an edge of the pixel electrode 171. The pixel-defining film 190 may be located in a third contact hole CT3. In other words, the third contact hole CT3 may be filled with the pixel-defining film 190. The pixel-defining film 190 may be formed as an organic film made of an acryl resin, an epoxy resin, a phenolic resin, a polyamide resin, a polyimide resin, or the like.

A spacer 191 may be located on the pixel-defining film 190. The spacer 191 may serve to support a mask during a process of manufacturing the light-emitting layer 172. The spacer 191 may be formed as an organic film made of an acryl resin, an epoxy resin, a phenolic resin, a polyamide resin, a polyimide resin, or the like.

The light-emitting layer 172 is formed on the pixel electrode 171. The light-emitting layer 172 may include an organic material to emit light of a color (e.g., predetermined color). For example, the light-emitting layer 172 may include a hole-transporting layer, an organic material layer, and an electron-transporting layer. The organic material layer may include a host and a dopant. The organic material layer may include a material that emits a light (e.g., predetermined light), and may be formed of a phosphorescent material or a fluorescent material.

The common electrode 173 is formed on the light-emitting layer 172. The common electrode 173 may be formed to cover the light-emitting layer 172. The common electrode 173 may be a common layer commonly formed in the light-emitting areas EA. A capping layer may be formed on the common electrode 173.

In the top emission structure, the common electrode 173 may be formed of a transparent conductive material (TCO), such as ITO or IZO capable of transmitting light, or a semi-transmissive conductive material, such as magnesium (Mg), silver (Ag), or an alloy of magnesium (Mg) and silver (Ag). When the common electrode 173 is formed of the semi-transmissive conductive material, light-emitting efficiency may be increased by a micro cavity.

The encapsulation layer ENC may be located on the light-emitting element layer EML. The encapsulation layer ENC may include one or more inorganic films TFE1 and TFE3 to reduce or prevent permeation of oxygen or moisture into the light-emitting element layer EML. In addition, the encapsulation layer ENC may include at least one organic film TFE2 to protect the light-emitting element layer EML from foreign substances, such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be located on the common electrode 173, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as a multi-film in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, or a polyimide resin.

The sensor electrode layer SENL may be located on the encapsulation layer ENC. The sensor electrode layer SENL may include a second buffer film BF2, a first connection portion BE1, a first sensor insulating film TINS1, sensor electrodes TE and RE, and a second sensor insulating film TINS2.

The second buffer film BF2 may be located on the encapsulation layer ENC. The second buffer film BF2 may include at least one inorganic film. For example, the second buffer film BF2 may be formed as a multi-film in which one or more inorganic films of a silicon nitride layer, a silicon oxynitride layer, a silicon oxide layer, a titanium oxide layer, or an aluminum oxide layer are alternately stacked. The second buffer film BF2 may be omitted.

The first connection portions BE1 may be located on the second buffer film BF2. The first connection portions BE1 may be formed as a single layer made of molybdenum (Mo), titanium (Ti), copper (Cu), or aluminum (Al) or be formed in a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The first sensor insulating film TINS1 may be located on the first connection portions BE1. The first sensor insulating film TINS1 may be formed as an inorganic film, for example, a silicon nitride layer, a silicon oxynitride layer, a silicon oxide layer, a titanium oxide layer, or an aluminum oxide layer.

Sensor electrodes, that is, driving electrodes TE and sensing electrodes RE, may be located on the first sensor insulating film TNIS1. In addition, dummy patterns may be located on the first sensor insulating film TNIS1. The driving electrodes TE, the sensing electrodes RE, and the dummy patterns do not overlap the light-emitting areas EA. The driving electrodes TE, the sensing electrodes RE, and the dummy patterns may be formed as a single layer made of molybdenum (Mo), titanium (Ti), copper (Cu), or aluminum (Al), or be formed in a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The second sensor insulating film TINS2 may be located on the driving electrodes TE, the sensing electrodes RE, and the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may be made of an acrylic resin, an epoxy resin, a phenolic resin, a polyamide resin, or a polyimide resin.

A polarizing film PF may be located on the sensor electrode layer SENL. The polarizing film PF may be located on the display panel 100 to reduce reflection of external light. The polarizing film PF may include a first base member, a linear polarizing plate, a phase retardation film, such as a quarter-waver (λ/4) plate, and a second base member. The first base member, the phase retardation film, the linear polarizing plate, and the second base member of the polarizing film PF may be sequentially stacked on the display panel 100.

A cover window CW may be located on the polarizing film PF. The cover window CW may be attached onto the polarizing film PF by a transparent adhesive member, such as an optically clear adhesive (OCA) film.

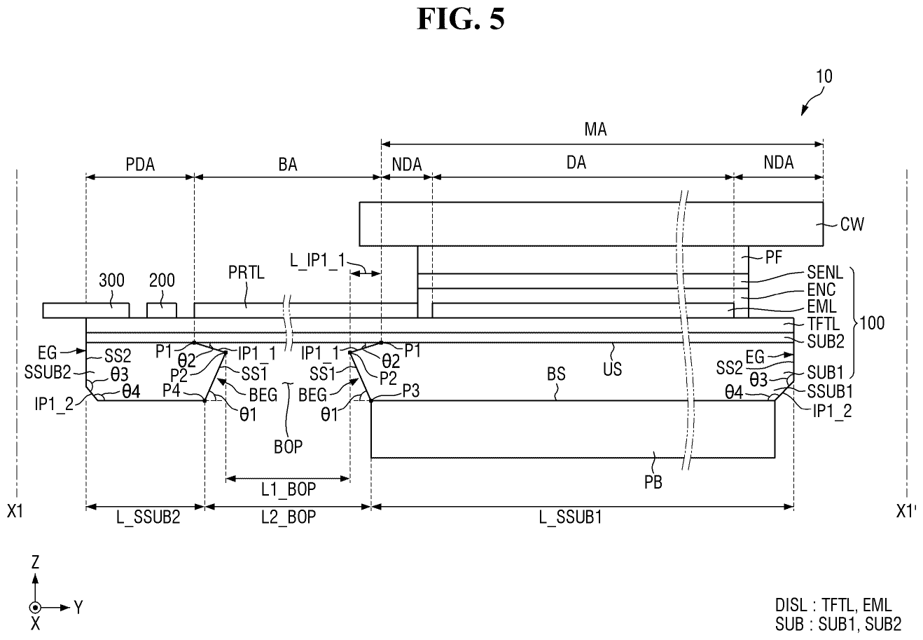

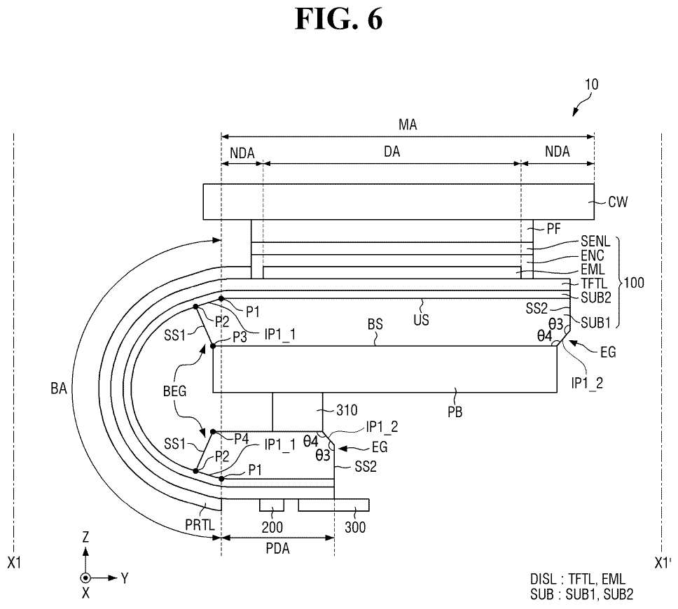

FIG. 5 is a cross-sectional view taken along the line X1-X1′ of FIG. 1. FIG. 6 is a cross-sectional view illustrating a state in which the display device according to one or more embodiments of FIG. 5 is bent.

Referring to FIGS. 5 and 6, the display device 10 may further include a protective film PRTL and a panel lower cover PB, in addition to the display panel 100, the polarizing film PF, the cover window CW, the driving IC 200, and the circuit board 300. The display panel 100 may include a substrate SUB, a display layer DISL, an encapsulation layer ENC, and a sensor electrode layer SENL.

Because the display layer DISL, the encapsulation layer ENC, the sensor electrode layer SENL, the polarizing film PF, and the cover window CW have been described above, a description thereof will be omitted.

The substrate SUB may include a first substrate SUB1 having a hard material and a second substrate SUB2 made of a polymer resin having a soft material. The first substrate SUB1 may not be located in the bending area BA. For example, the first substrate SUB1 may include, or define, an opening BOP exposing the second substrate SUB2. That is, because the first substrate SUB1 made of a hard material is not located in the bending area BA, the display device 10 may be easily bent as illustrated in FIG. 6.

The protective film PRTL may be located on the thin film transistor layer TFTL in the bending area BA. The protective film PRTL may be a layer to protect the thin film transistor layer TFTL exposed to the outside in the bending area BA. The protective film PRTL may be formed of an organic material, such as an acryl resin, an epoxy resin, a phenolic resin, a polyamide resin, a polyimide resin, or the like.

The panel lower cover PB may be located on a second surface of the first substrate SUB1 of the display panel 100. The second surface of the first substrate SUB1 may be a surface opposite to the first surface. For example, the panel lower cover PB may be located on a lower surface BS of the first substrate SUB1. The panel lower cover PB may be attached to the second surface of the first substrate SUB1 of the display panel 100 through an adhesive member. The adhesive member may be a pressure sensitive adhesive (PSA).

The panel lower cover PB may include at least one of a light-blocking member for absorbing light incident from the outside, a buffer member for absorbing a shock from the outside, or a heat dissipation member for efficiently dissipating heat of the display panel 100.

The driving IC 200 and the circuit board 300 may be bent toward the lower portion of the display panel 100, as illustrated in FIG. 6. The pad area PDA of the display panel 100 to which the driving IC 200 and the circuit board 300 are attached may be attached to a lower surface of the panel lower cover PB using an adhesive member 310.

The adhesive member 310 may be a pressure sensitive adhesive. The adhesive member 310 may be located between the first substrate SUB1 located in the main area MA, and the first substrate SUB1 located in the pad area PDA, in a state in which the display device 10 is bent. The adhesive member 310 may be located below the panel lower cover PB.

In the display device 10, the first substrate SUB1 may include an upper surface US, a lower surface BS, a first side surface SS1, a first inclined surface IP1_1, a second side surface SS2, and a second inclined surface IP1_2.

The upper surface US of the first substrate SUB1 may be a surface on a side in the third direction (Z-axis direction), and the lower surface BS thereof may be a surface on a side opposite thereto in the third direction (Z-axis direction).

The first side surface SS1 may be positioned at an edge BEG of the bending area BA. The edge BEG of the bending area BA may refer to an edge formed by etching the first substrate SUB1 on the bending area BA.

The first side surface SS1 may be positioned between the upper surface US and the lower surface BS. The first side surface SS1 may be positioned at an edge BEG of the bending area BA. The first side surface SS1 may be an inclined surface.

For example, as illustrated in FIG. 5, a first angle θ1, which is an acute angle formed between the lower surface BS and the first side surface SS1 of the first substrate SUB1, may be less than approximately 60 degrees. In one or more embodiments, the first angle θ1 may be approximately 45 degrees to 50 degrees.

The inclined surface of the first side surface SS1 may be formed when a protective film is attached, and a portion of the first substrate SUB1 on the bending area BA may be etched during the process of manufacturing the display device 10. For example, by attaching a protective film to the remaining area of the first substrate SUB1 excluding the bending area BA, only the first substrate SUB1 positioned in the bending area BA may be etched first. The first substrate SUB1 positioned in the bending area BA may be formed as an inclined surface due to isotropy of wet etching. After the first substrate SUB1 positioned in the bending area BA is etched to a certain thickness, the entirety of the first substrate SUB1 may be etched by removing the protective film. Through this, a thickness of the first substrate SUB1 may be reduced, and at the same time, an opening BOP exposing the second substrate SUB2 may be formed in the bending area BA.

Accordingly, the first substrate SUB1 may include a first sub-substrate SSUB1 positioned on one side of the opening BOP, and a second sub-substrate SSUB2 positioned on the other side of the opening BOP.

The first inclined surface IP1_1 may be positioned between the upper surface US and the first side surface SS1. The first inclined surface IP1_1 may be an undercut formed between the first substrate SUB1 and the second substrate SUB2. The first inclined surface IP1_1 may be formed due to overetching of an etchant that has permeated into an interface between the first substrate SUB1 and the second substrate SUB2 when the first substrate SUB1 is etched during the process of manufacturing the display device 10.

In some embodiments, as illustrated in FIG. 5, a length L_IP1_1 of the first inclined surface IP1_1 in the second direction (Y-axis direction) may be approximately 120 μm or less. The length L_IP1_1 of the first inclined surface IP1_1 in the second direction (Y-axis direction) may refer to a distance in the second direction (Y-axis direction) from an end P2 at the edge BEG of the bending area BA of the first substrate SUB1 to a boundary P1 where the first inclined surface IP1_1 and the upper surface US of the first substrate SUB1 meet. In one or more embodiments, a second angle θ2, which is an acute angle formed between the first inclined surface IP1_1 and the upper surface US of the first substrate SUB1, may be less than approximately 15 degrees.

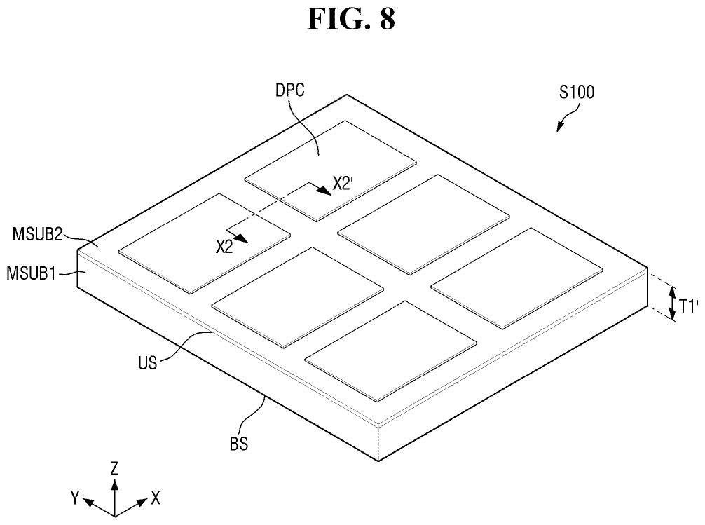

The second side surface SS2 may be positioned at an edge EG of the display panel 100. The edge EG of the display panel 100 may refer to an edge formed by etching the first substrate SUB1 along a perimeter of a display cell DPC (see FIG. 8), which will be described later.

The second side surface SS2 may be positioned between the upper surface US and the lower surface BS. The second side surface SS2 may be positioned at an edge EG of the display panel 100. The second side surface SS2 may be a substantially vertical surface, but is not limited thereto.

The second inclined surface IP1_2 may be positioned between the lower surface BS and the second side surface SS2. The second inclined surface IP1_2 may be positioned at an edge EG of the display panel 100. The second inclined surface IP1_2 may be formed due to isotropy of the etchant during a process of spraying the etchant after irradiating a laser in the process of manufacturing the display device 10.

In some embodiments, a third angle θ3, which is an angle formed between the second side surface SS2 and the second inclined surface IP1_2, and a fourth angle θ4, which is an angle formed between the second inclined surface IP1_2 and the lower surface BS, may be obtuse angles.

Because the first side surface SS1 is formed by the anisotropy resulting from concurrent or substantially simultaneous etching of the entire area after partial etching of the bending area BA, while the second inclined surface IP1_2 is formed by the laser irradiation and the isotropy of the etchant, the third angle θ3 and the fourth angle θ4 may be different from a supplementary angle of the first angle θ1. In addition, because the first inclined surface IP1_1 is an undercut due to permeation of the etchant, a supplementary angle of the second angle θ2 may be different from the third angle θ3 and the fourth angle θ4.

In the display device 10, a length L_SSUB1 of the first sub-substrate SSUB1 in the second direction (Y-axis direction) may be about 50 times to about 200 times a length L_SSUB2 of the second sub-substrate SSUB2 in the second direction (Y-axis direction). For example, the length L_SSUB2 of the second sub-substrate SSUB2 in the second direction (Y-axis direction) may be about 2 mm to about 4 mm, and the length L_SSUB1 of the first sub-substrate SSUB1 in the second direction (Y-axis direction) may be about 200 mm to about 400 mm.

The length L_SSUB1 of the first sub-substrate SSUB1 in the second direction (Y-axis direction) may refer to a distance from an end farthest from the opening BOP at one end of the first sub-substrate SSUB1 in the second direction (Y-axis direction), to a boundary P3 where the lower surface BS and the first side surface SS1 of the first sub-substrate SSUB1 meet. The length L_SSUB2 of the second sub-substrate SSUB2 in the second direction (Y-axis direction) may refer to a distance from an end farthest from the opening BOP at one end of the second sub-substrate SSUB2 in the second direction (Y-axis direction), to a boundary P4 where the lower surface BS and the first side surface SS1 of the first sub-substrate SSUB1 meet.

The length L_SSUB2 of the second sub-substrate SSUB2 in the second direction (Y-axis direction) may be about 1 to about 4 times a length L1_BOP of an upper side of the opening BOP in the second direction (Y-axis direction). For example, the length L1_BOP of the upper side of the opening BOP in the second direction (Y-axis direction) may be about 1.2 mm to about 1.8 mm.

The length L1_BOP of the upper side of the opening BOP in the second direction (Y-axis direction) may refer to a distance between the ends P2 at the edge BEG of the bending area BA of the first substrate SUB1.

The length L_SSUB2 of the second sub-substrate SSUB2 in the second direction (Y-axis direction) may be about 1 to about 2.5 times a length L1_BOP of a lower side of the opening BOP in the second direction (Y-axis direction). For example, the length L1_BOP of the lower side of the opening BOP in the second direction (Y-axis direction) may be about 1.6 mm to about 2.0 mm.

The length L2_BOP of the lower side of the opening BOP in the second direction (Y-axis direction) may refer to a distance between the boundaries P3 and P4, where the lower surface BS and the first side surface SS1 of the first substrate SSUB1 meet.

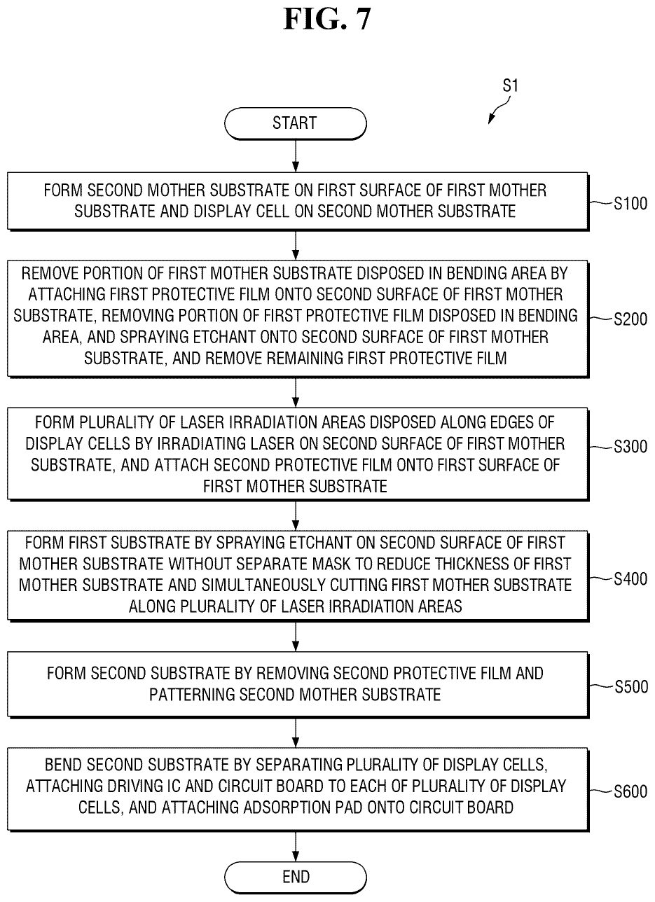

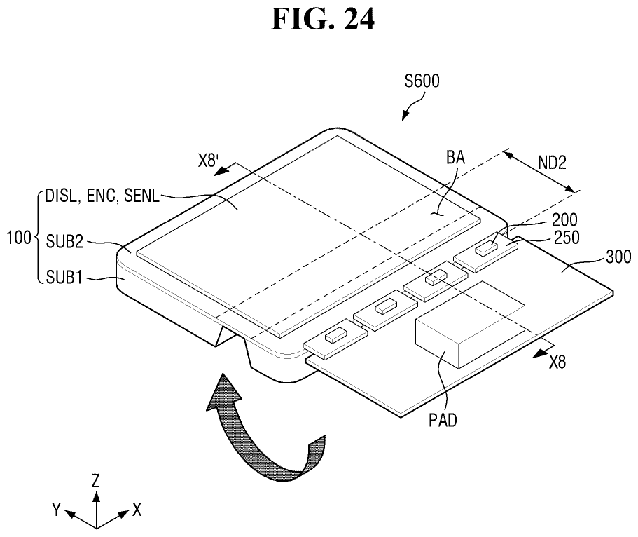

Because the display device 10 might not have the first substrate SUB1 located in the bending area BA, the amount of force suitable to bend the display device 10 may be relatively small. Accordingly, even if a bending adsorption pad PAD (see FIG. 24) is attached to the circuit board 300 when the display device 10 is bent, damage to the display device 10 may be reduced or minimized. Therefore, a spare space where the bending adsorption pad PAD may be attached may not be separately located in the bending area BA and the pad area PDA. Accordingly, by reducing or minimizing the length of the bending area BA and the pad area PDA, a gap between the display cells DPC (see FIG. 8) may be reduced or minimized in a method S1 for manufacturing the display device (see FIG. 7) described later, and a dead space of the display device 10 may be reduced or minimized.

Hereinafter, a method for manufacturing a display device according to one or more embodiments will be described.

FIG. 7 is a flowchart illustrating a method for manufacturing a display device according to one or more embodiments.

Referring to FIG. 7, a method S1 for manufacturing a display device according to one or more embodiments may include forming a second mother substrate on a first surface of a first mother substrate, and forming a display cell on the second mother substrate (S100), removing a portion of the first mother substrate located in a bending area by attaching a first protective film onto a second surface of the first mother substrate, removing a portion of the first protective film located in the bending area, and spraying an etchant onto the second surface of the first mother substrate, and removing the remaining first protective film (S200), forming a plurality of laser irradiation areas located along edges of a display cells by irradiating a laser on the second surface of the first mother substrate, and attaching a second protective film onto the first surface of the first mother substrate (S300), forming a first substrate by spraying an etchant on the second surface of the first mother substrate without a separate mask to reduce a thickness of the first mother substrate and concurrently or substantially simultaneously cutting the first mother substrate along the plurality of laser irradiation areas (S400), forming a second substrate by removing the second protective film and patterning the second mother substrate (S500), and bending the second substrate by separating the plurality of display cells, attaching a driving IC and a circuit board to each of the plurality of display cells, and attaching an adsorption pad onto the circuit board (S600).

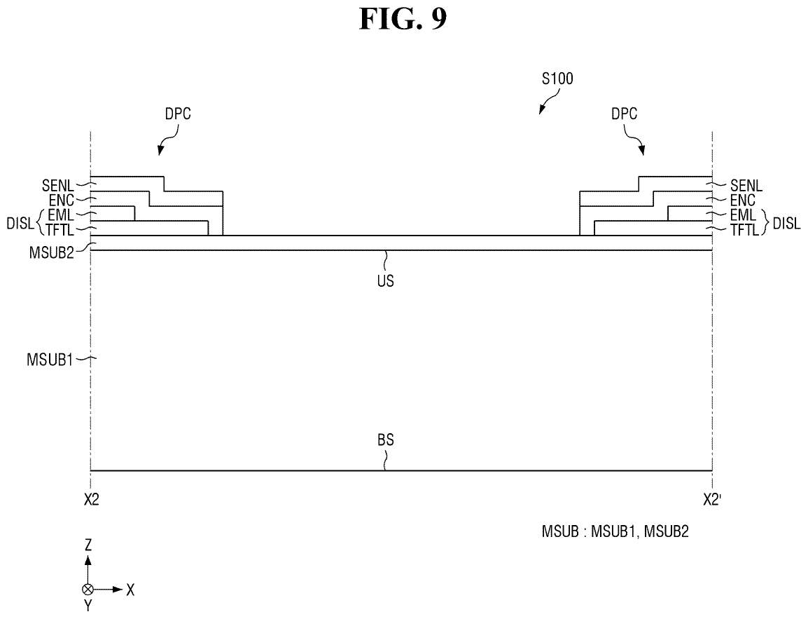

FIG. 8 is a perspective view illustrating operation S100 of FIG. 7. FIG. 9 is a cross-sectional view taken along the line X2-X2′ of FIG. 8.

Referring to FIGS. 8 and 9 in addition to FIG. 7, a second mother substrate may be formed on a first surface of a first mother substrate, and a display cell may be formed on the second mother substrate (S100 in FIG. 7).

A mother substrate MSUB may include a first mother substrate MSUB1 and a second mother substrate MSUB2. The second mother substrate MSUB2 may be located on the first mother substrate MSUB1. The first mother substrate MSUB1 may have a hard material. The second mother substrate MSUB2 may have a soft material.

Each display cell DPC may include a first mother substrate MSUB1, a second mother substrate MSUB2 located on an upper surface US of a first mother substrate MSUB1, a display layer DISL located on the second mother substrate MSUB2, an encapsulation layer ENC located on the display layer DISL, and a sensor electrode layer SENL located on the encapsulation layer ENC. The display layer DISL may include a thin film transistor layer TFTL and a light-emitting element layer EML.

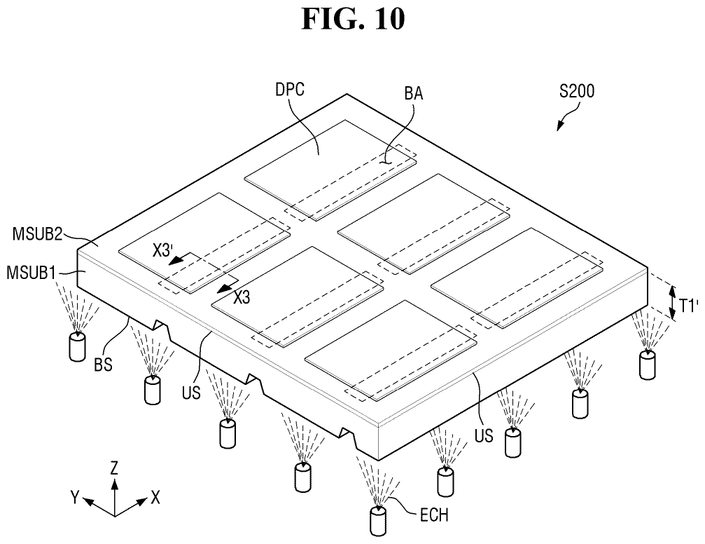

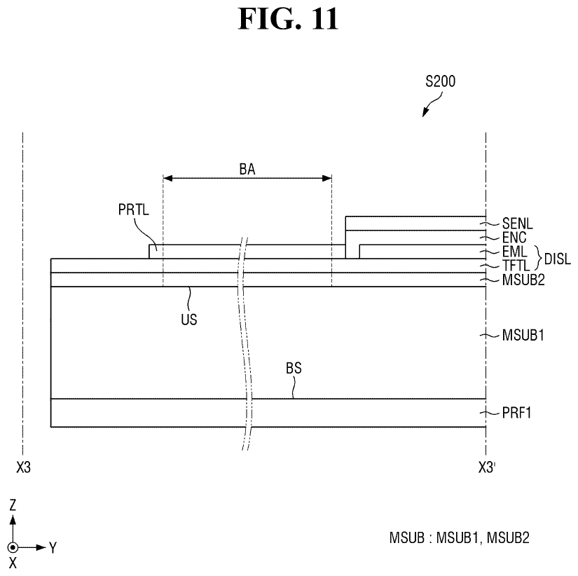

FIG. 10 is a perspective view illustrating operation S200 of FIG. 7. FIGS. 11 to 14 are cross-sectional views taken along the line X3-X3′ of FIG. 10.

Referring to FIGS. 10 to 14, in addition to FIG. 7, a portion of the first mother substrate located in a bending area may be removed by attaching a first protective film onto a second surface of the first mother substrate, removing a portion of the first protective film located in the bending area, and spraying an etchant onto the second surface of the first mother substrate, and the remaining first protective film may be removed (S200 in FIG. 7).

As illustrated in FIG. 11, a first protective film PRF1 may be attached onto a rear surface of the mother substrate MSUB, for example, a lower surface BS of the first mother substrate MSUB1. The first protective film PRF1 may be an acid-resistant film. The first protective film PRF1 may reduce or prevent etching of the first mother substrate MSUB1 in the area where the first protective film PRF1 is attached.

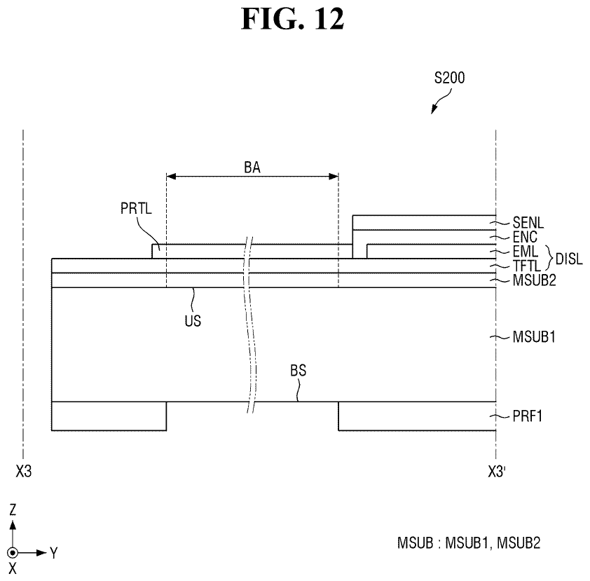

Next, as illustrated in FIG. 12, the first protective film PRF1 located in the bending area BA may be removed. The lower surface BS of the first mother substrate MSUB1 may be exposed in the bending area BA where the first protective film PRF1 is removed.

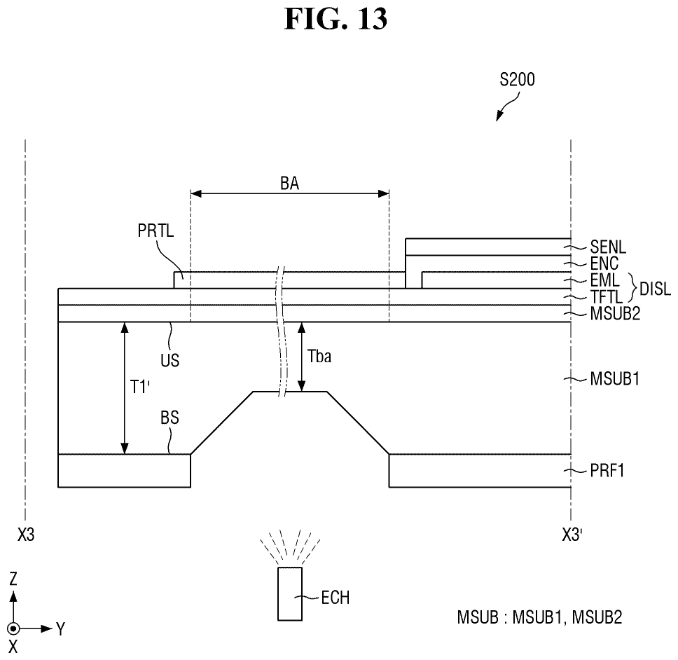

Next, as illustrated in FIG. 13, a portion of the first mother substrate MSUB1 located in the bending area BA may be etched by spraying an etchant ECH onto the lower surface BS of the first mother substrate MSUB1. As a result, a portion of the first mother substrate MSUB1 located in the bending area BA may be removed. A thickness Tba of the first mother substrate MSUB1 in the bending area BA may be less than a first thickness T1′ of the first mother substrate MSUB1 in the remaining areas excluding the bending area BA.

After the first mother substrate MSUB1 is etched, an inclined surface may be formed in the bending area BA. Such an inclined surface may be formed by isotropy of wet etching.

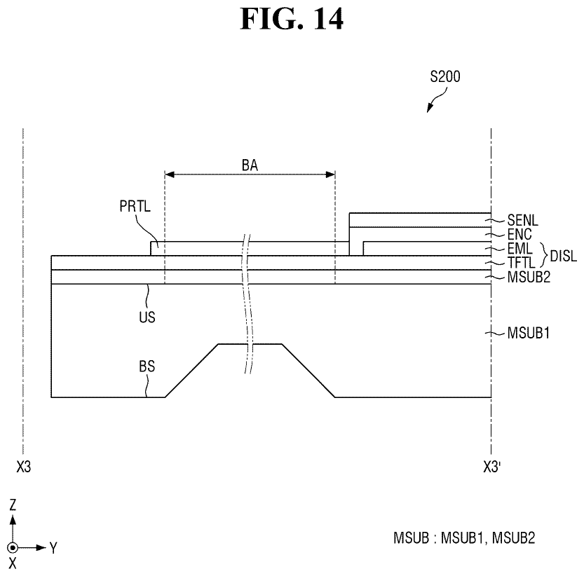

Next, as illustrated in FIG. 14, the first protective film PRF1 may be removed.

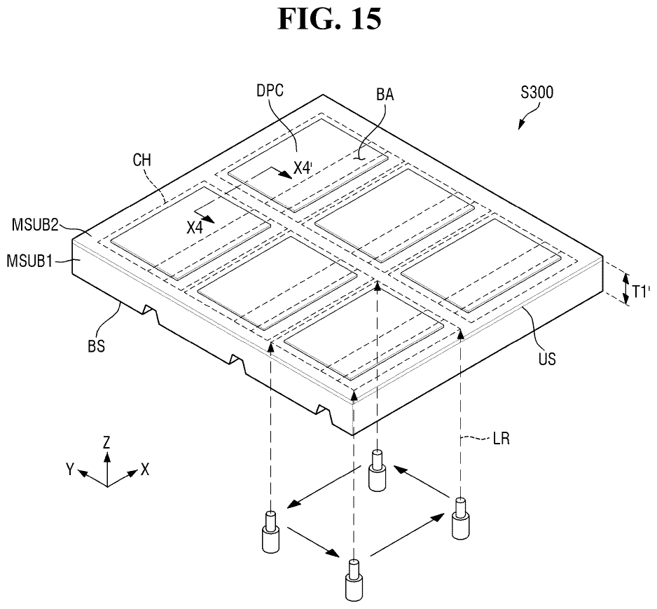

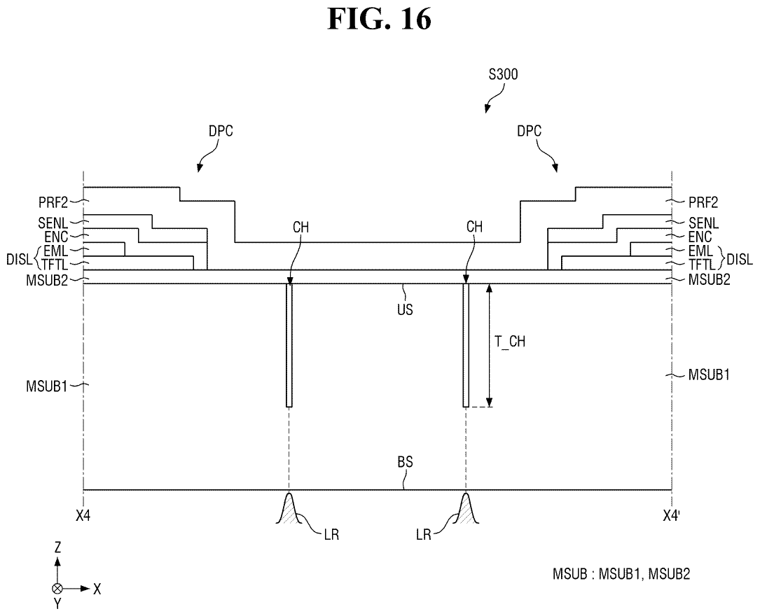

FIG. 15 is a perspective view illustrating operation S300 of FIG. 7. FIG. 16 is a cross-sectional view taken along the line X4-X4′ of FIG. 15.

Referring to FIGS. 15 and 16, in addition to FIG. 7, a plurality of laser irradiation areas located along edges of a display cells may be formed by irradiating a laser on the second surface of the first mother substrate, and a second protective film may be attached onto the first surface of the first mother substrate (S300 in FIG. 7).

Various lasers LR may be used according to one or more embodiments. For example, the laser LR according to one or more embodiments may be an infrared Bessel beam with a wavelength of approximately 1030 nm, but is not limited thereto.

The laser LR may be irradiated on the second surface, for example, the lower surface BS, of the first mother substrate MSUB1. However, the present specification is not limited thereto, and the laser LR may also be irradiated on the first surface, for example, the upper surface US, of the first mother substrate MSUB1.

A sketch line may be defined as a virtual line connecting a plurality of laser irradiation areas CH. The sketch line may be formed by irradiating the laser LR to form the plurality of laser irradiation areas CH along the edges of the plurality of display cells DPC.

When the laser LR is irradiated on the lower surface BS of the first mother substrate MSUB1, a depth (or sketch length) T_CH of each of the plurality of laser irradiation areas CH may be adjusted according to the repetition rate, processing speed, and pulse energy.

For example, the depth T_CH of each of the plurality of laser irradiation areas CH may be less than the thickness of the first mother substrate MSUB1. As an example, when the thickness of the first mother substrate MSUB1 is approximately 500 μm, the depth T_CH of each of the plurality of laser irradiation areas CH may be about 50 μm to about 300 μm. However, the depth T_CH of each of the plurality of laser irradiation areas CH is not limited thereto, and may also be the same as the thickness of the first mother substrate MSUB1.

In one or more embodiments, the laser LR for forming the plurality of laser irradiation areas CH may be irradiated with a repetition rate of about 1 kHz to about 250 kHz, a processing speed of about 1 mm/s to about 250 mm/s, and a pulse energy of about 10 uJ to about 300 uJ, but is not limited thereto.

Next, a second protective film PRF2 may be attached on an upper surface US of the first mother substrate MSUB1, for example, on the plurality of display cells DPC. The second protective film PRF2 may cover all of the plurality of display cells DPC at once. The second protective film PRF2 may cover the plurality of display cells DPC and the second mother substrate MSUB2.

The second protective film PRF2 may be an acid-resistant film. The second protective film PRF2 may protect the plurality of display cells DPC from the etchant ECH during the etching process of the first mother substrate MSUB1.

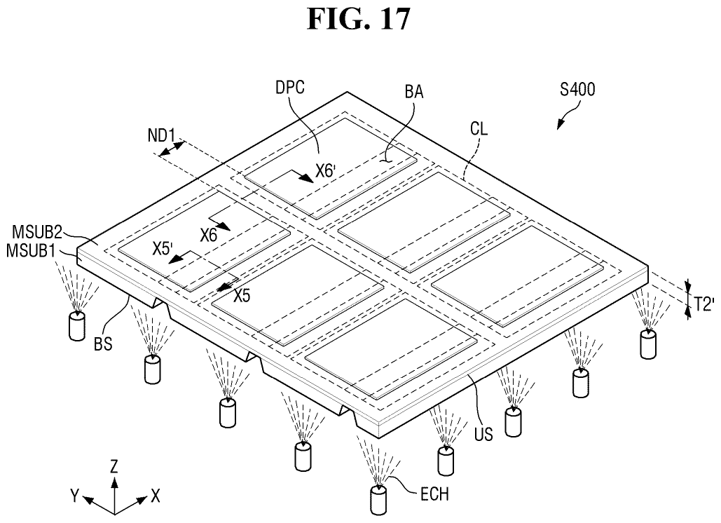

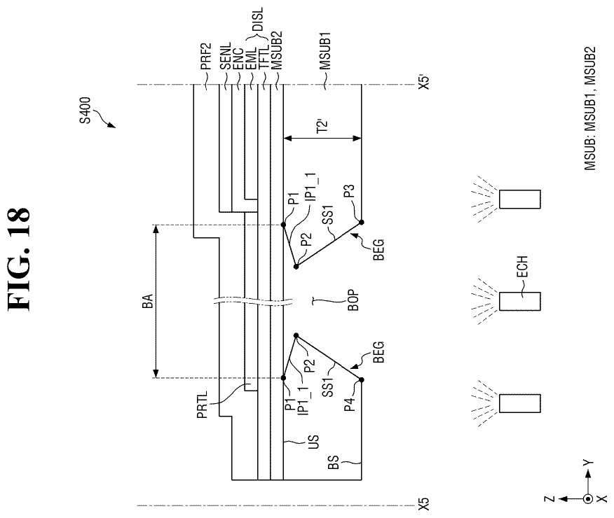

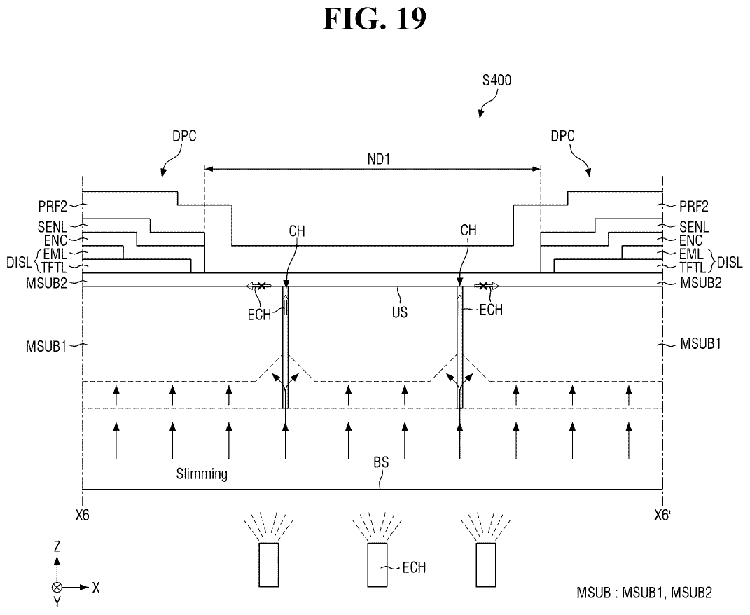

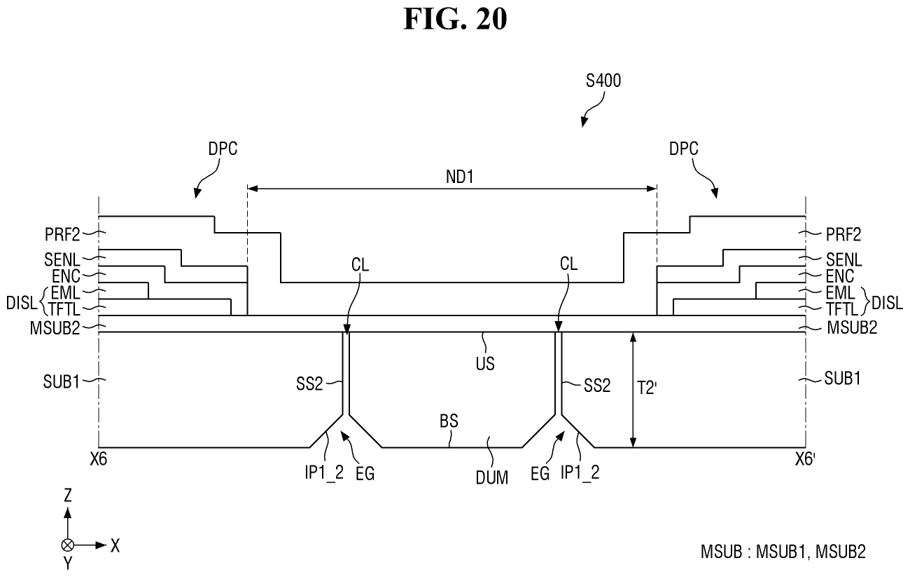

FIG. 17 is a perspective view illustrating operation S400 of FIG. 7. FIG. 18 is a cross-sectional view taken along the line X5-X5′ of FIG. 17. FIGS. 19 and 20 are cross-sectional views taken along the line X6-X6′ of FIG. 17.

Referring to FIGS. 17 to 20 in addition to FIG. 7, a first substrate may be formed by spraying an etchant on the second surface of the first mother substrate without a separate mask to reduce a thickness of the first mother substrate, and concurrently or substantially simultaneously cutting the first mother substrate along the plurality of laser irradiation areas (S400 in FIG. 7).

When the etchant ECH is sprayed on the lower surface BS of the first mother substrate MSUB1, the first mother substrate MSUB1 may be reduced from the first thickness T1′ to a second thickness T2′. The first thickness T1′ may be approximately 500 μm, and the second thickness T2′ may be approximately 200 μm, but are not limited thereto.

Because the first mother substrate MSUB1 is etched without the separate mask, the first mother substrate MSUB1 may be isotropically etched uniformly over the entire area of the lower surface BS.

As illustrated in FIGS. 19 and 20, each of the plurality of laser irradiation areas CH may include a physical hole formed by the laser LR, and an area around the physical hole whose physical properties are changed by the laser. Alternatively, each of the plurality of laser irradiation areas CH may also be an area whose physical properties are changed by the laser LR without a physical hole. As a result, an etching rate in each of the plurality of laser irradiated areas CH by the etchant ECH may be higher than an etching rate in other areas of the first mother substrate MSUB1 that is not irradiated with the laser.

When the thickness of the first mother substrate MSUB1 is reduced by the etchant ECH and the etchant ECH permeates into the plurality of laser irradiation areas CH formed by the laser LR, there may be a difference in etching speed between the area where the laser irradiation areas CH are formed and the area where the laser irradiation areas CH are not formed, due to the plurality of laser irradiation areas CH. That is, anisotropic etching in which the etching speed in the area where the laser irradiation areas CH are formed is faster than the etching speed in the area where the laser irradiation areas CH are not formed may be performed on the first mother substrate MSUB1. As a result, the first substrate SUB1 formed separately from the first mother substrate MSUB1 may include a second side surface SS2 at the edge EG of the display panel 100, and a second inclined surface IP1_2 located between the second side surface SS2 and the lower surface BS.

As the etchant ECH permeates into the plurality of laser irradiation areas CH formed by the laser LR, a cutting line CL may be formed along the plurality of laser irradiation areas CH. The first substrate SUB1 may be separated from a dummy DUM of the first mother substrate MSUB1 along the cutting line CL. The dummy DUM may be a portion of the first mother substrate MSUB1 formed by the remaining first mother substrate MSUB1.

Meanwhile, as illustrated in FIG. 18, the first mother substrate MSUB1 may be etched in the bending area BA and adjacent areas. As illustrated in FIG. 14, because the first mother substrate MSUB1 on which the inclined surface is formed is etched once more in operation S200, the shape of the edge BEG of the bending area BA may be different from the shape of the edge EG of the display panel 100 illustrated in FIGS. 19 and 20. As illustrated in FIG. 18, at the edge BEG of the bending area BA, the first side surface SS1, the first inclined surface IP1_1 located between the first side surface SS1 and the upper surface US, and the opening BOP may be formed.

In the method S1 for manufacturing the display device, the process of etching the first mother substrate MSUB1 may be performed before a process of patterning the second mother substrate MSUB2, which will be described later.

In this case, as illustrated in FIG. 19, permeation of the etchant ECH from the plurality of laser irradiation areas CH into the display cell DPC may be reduced or minimized by the second mother substrate MSUB2 located on the first mother substrate MSUB1 in the area between the display cells DPC. Accordingly, because additional margins are unnecessary to reduce or prevent damage to the display cells DPC due to permeation of the etchant ECH, a distance ND1 between the display cells DPC may be reduced or minimized. Therefore, an area efficiency occupied by the display cell DPC compared to a size of the mother substrate MSUB may be increased.

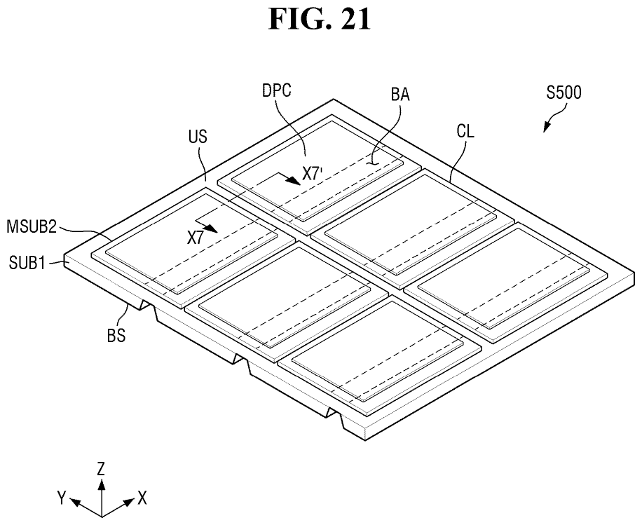

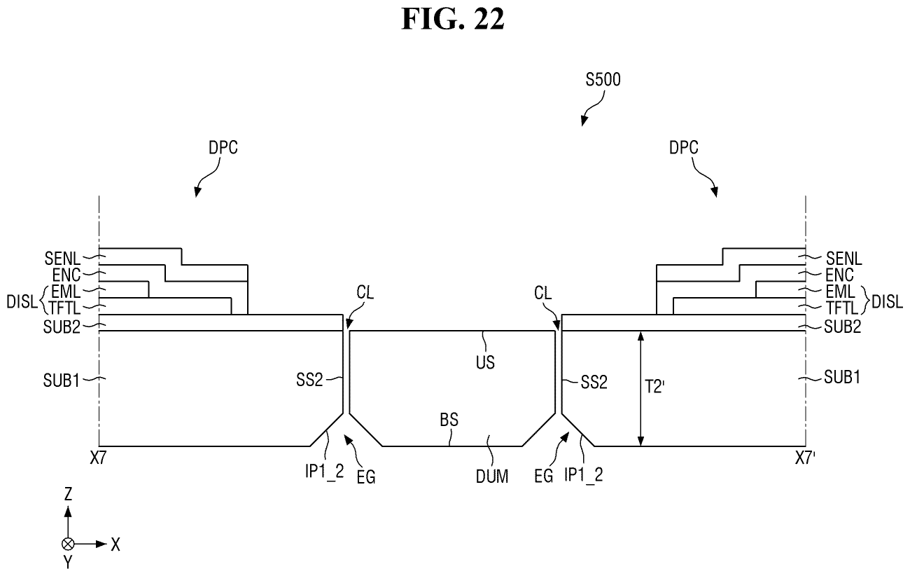

FIG. 21 is a perspective view illustrating operation S500 of FIG. 7. FIG. 22 is a cross-sectional view taken along the line X7-X7′ of FIG. 21.

Referring to FIGS. 21 and 22 in addition to FIG. 7, a second substrate may be formed by removing the second protective film, and patterning the second mother substrate (S500 in FIG. 7).

After the process of etching the first mother substrate MSUB1 is completed, the second protective film PRF2 may be removed.

Next, as illustrated in FIGS. 21 and 22, the second mother substrate MSUB2 may be patterned along edges of the display cells DPC. A second substrate SUB2 may be formed by patterning the second mother substrate MSUB2.

As an example, the second mother substrate MSUB2 may be patterned so that the edge of the second mother substrate MSUB2 is formed along the cutting line CL formed in the process of etching the first mother substrate MSUB1. In this case, the edge of the second substrate SUB2 may coincide with the edge of the first substrate SUB1. However, the present disclosure is not limited thereto, and as another example, the edge of the second substrate SUB2 may be positioned between the edge of the display cell DPC and the edge of the first substrate SUB1.

The second substrate SUB2 may be removed from the dummy DUM. Each of the plurality of display cells DPC may be separated from the first mother substrate MSUB1 (or dummy DUM). Finally, each of the plurality of display cells DPC may include a first substrate SUB1, a second substrate SUB2, a display layer DISL, an encapsulation layer ENC, and a sensor electrode layer SENL.

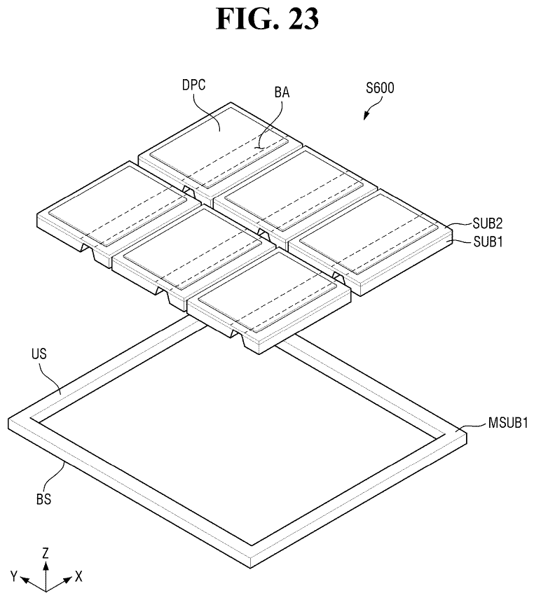

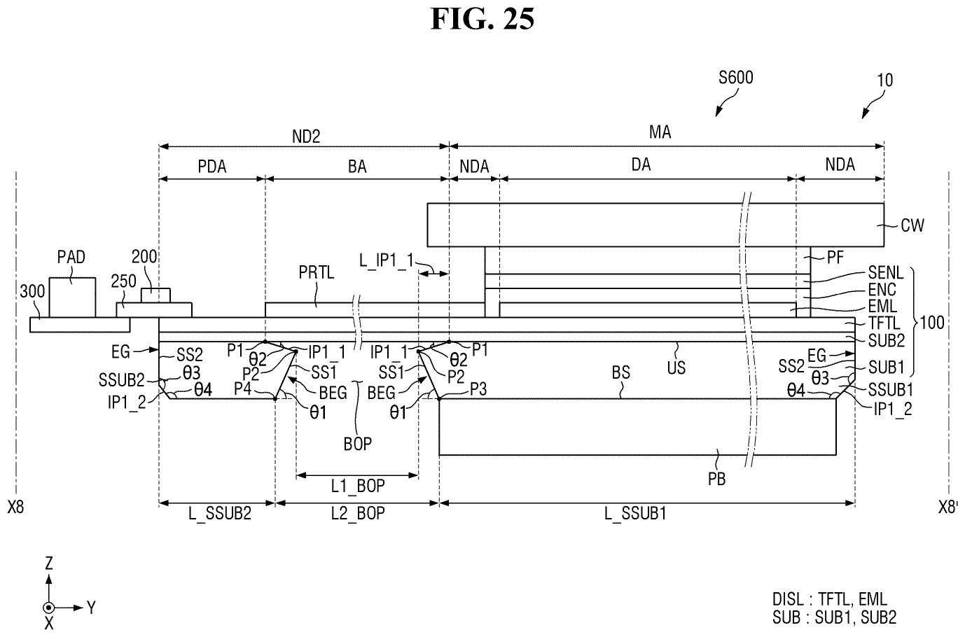

FIGS. 23 and 24 are perspective views illustrating operation S600 of FIG. 7. FIG. 25 is a cross-sectional view taken along the line X8-X8′ of FIG. 24.

Referring to FIGS. 23 to 25 in addition to FIG. 7, the second substrate may be bent by separating the plurality of display cells, attaching a driving IC and a circuit board to each of the plurality of display cells, and attaching an adsorption pad onto the circuit board (S600 in FIG. 7).

As illustrated in FIG. 23, each of the plurality of display cells DPC may be separated from the first mother substrate MSUB1 (or dummy DUM).

As illustrated in FIGS. 24 and 25, a driving IC 200 and a circuit board 300 may be attached to each of the plurality of display cells DPC. In some embodiments, a connection film 250 may be further attached depending on a mounting method of the driving IC 200.

In the method S1 for manufacturing the display device, the bending adsorption pad PAD may be attached onto the circuit board 300. When the bending adsorption pad PAD is attached onto the second substrate SUB2, an attachment tolerance of the adsorption pad PAD may be suitably considered. Therefore, a length ND2 of the bending area BA and the pad area PDA in the second direction (Y-axis direction) may be increased. On the other hand, according to the method S1 for manufacturing the display device, because the adsorption pad PAD is attached onto the circuit board 300, a separate attachment tolerance for the adsorption pad PAD is not necessary, thereby reducing or minimizing a dead space of the display device 10.

The second substrate SUB2 may be bent along the bending area BA by applying force in the third direction (Z-axis direction) to the adsorption pad PAD. Because the first substrate SUB1 made of a hard material is not located in the bending area BA, relatively less force may be applied to the adsorption pad PAD to bend the second substrate SUB2. Therefore, damage to a bonding area of the circuit board 300 and the connection film 250 may be reduced or minimized.

In concluding the detailed description, those skilled in the art will appreciate that many variations and modifications can be made to the preferred embodiments without substantially departing from the principles of the present disclosure. Therefore, the disclosed preferred embodiments of the present disclosure are used in a generic and descriptive sense only and not for purposes of limitation.

What is claimed is:

1. A display device comprising:
a second substrate comprising a soft material;
light-emitting elements above the second substrate; and
a first substrate below the second substrate, comprising a hard material, and further comprising:
a second sub-substrate on one side of a bending area where the second substrate is bent; and
a first sub-substrate on another side of the bending area, below the light-emitting elements, having a length that is about 50 times to about 200 times a length of the second sub-substrate, and comprising:
a first surface;
a second surface opposite to the first surface;
a first side surface between the first surface and the second surface, and adjacent to the bending area; and
a first inclined surface between the first surface and the first side surface.

2. The display device of claim 1, wherein the length of the second sub-substrate is about 2 mm to about 4 mm.

3. The display device of claim 2, wherein the length of the first sub-substrate is about 200 mm to about 400 mm.

4. The display device of claim 1, wherein the first substrate defines an opening between the first sub-substrate and the second sub-substrate, and
wherein a length of an upper side of the opening is less than a length of a lower side of the opening.

5. The display device of claim 4, wherein the length of the second sub-substrate is about 1 to about 4 times the length of the upper side of the opening.

6. The display device of claim 5, wherein the length of the upper side of the opening is about 1.2 mm to about 1.8 mm.

7. The display device of claim 4, wherein the length of the second sub-substrate is about 1 to about 2.5 times the length of the lower side of the opening.

8. The display device of claim 7, wherein the length of the lower side of the opening is about 1.6 mm to about 2.0 mm.

9. The display device of claim 1, wherein an angle between the first side surface and the second surface is less than about 60 degrees.

10. The display device of claim 1, wherein an angle formed by the first inclined surface and the first surface is less than about 15 degrees.

11. The display device of claim 10, wherein a length of the first inclined surface is about 120 μm or less.

12. The display device of claim 10, wherein the first substrate further comprises:
a second side surface between the first surface and the second surface, and adjacent to an edge of the first substrate; and
a second inclined surface between the second side surface and the first surface.

13. The display device of claim 12, wherein an angle formed by the second inclined surface and the second surface is different from an angle formed by the first side surface and the second surface.

14. The display device of claim 1, wherein the first substrate comprises glass, and wherein the second substrate comprises polymer resin.

15. A method for manufacturing a display device, the method comprising:
forming a first mother substrate, a second mother substrate above a first surface of the first mother substrate, and display cells on the second mother substrate;
removing a portion of the first mother substrate in a bending area by spraying an etchant onto a second surface of the first mother substrate that is opposite to the first surface;
irradiating a laser on the second surface along edges of the display cells;
forming a first substrate by spraying an etchant on the second surface without a mask, and by cutting the first mother substrate; and
forming a second substrate by patterning the second mother substrate along the edges of the display cells after the forming of the first substrate.

16. The method of claim 15, wherein the first substrate comprises:
a third surface;
a fourth surface opposite to the third surface;
a first side surface between the third surface and the fourth surface, and adjacent to the bending area; and
a first inclined surface between the third surface and the first side surface, and adjacent to the bending area.

17. The method of claim 16, wherein the first substrate further comprises:
a second side surface between the third surface and the fourth surface, and adjacent to edges of the display cells; and
a second inclined surface between the second side surface and the fourth surface, and adjacent to edges of the display cells,
wherein an angle formed by the first side surface and the fourth surface is different from an angle formed by the second inclined surface and the fourth surface.

18. The method of claim 15, wherein the forming of the first substrate comprises forming dummies form a remainder of the first mother substrate between the display cells below the second mother substrate.

19. The method of claim 18, wherein the forming of the second substrate comprises removing the second mother substrate above the dummies by patterning the second mother substrate.

20. The method of claim 15, further comprising attaching a circuit board and an adsorption pad to each of the display cells, and bending the second substrate,
wherein the adsorption pad is attached onto the circuit board.
